(19) United States
(12) Patent Application Publication
(10) Pub. No.: US 2025/0243052 A1
(43) Pub. Date: Jul. 31, 2025

(54) Single MEMS Die Capable of Differential SPDT or General DPDT

(71) Applicant: Menlo Microsystems, Inc., Irvine, CA (US)

(72) Inventor: Xu Zhu, Belmont, MA (US)

(21) Appl. No.: 18/428,720

(22) Filed: Jan. 31, 2024

(51) Int. Cl. B81B 7/04

(52) U.S. Cl. CPC B81B 7/04; B81B 2201/01; B81B 2207/07

(57) ABSTRACT

A micro-electrical-mechanical-system (MEMS) switching device including a first MEMS switch having a first and second terminal, and a second MEMS switch having a third and fourth terminal. The device also includes first and second input conductors, and first and second output conductors. The first input conductor electrically connects the second terminal to the third terminal. The second input conductor electrically connects an input port to the first input conductor. The first output conductor electrically connects a first output port to the first terminal. The second output conductor electrically connects a second output port to the fourth terminal. A first path from the input port to the first output port, and a second path from the input port to the second output port, have substantially identical electrical characteristics.

### BACKGROUND

Microelectromechanical system (MEMS) switches are an emerging technology for high power radio frequency (RF) and microwave switch applications. These devices offer the same power handling and RF performance of an electromechanical (EM) relay with the size, weight, reliability and speed of a solid-state device.

A differential signal may be used to transmit a high-rate data stream. A differential signal is transmitted using a differential pair, in which the signal carried by one transmission path of the pair is the same voltage level as the signal carried by the other transmission path (e.g., wire) of the pair but in opposite polarity. The receiver of the differential signal interprets the differential signal as the difference between the signals on the two transmission paths that make up the differential pair. An application using a differential signal may require the differential signal to be switched between a first differential output and a second differential output. This requirement may be implemented by a differential single-pole-double-throw (SPDT) switch.

Existing SPDT switch implementations are currently performed either with discrete switches packages mounted on a printed circuit board (PCB), or with a discrete switch die mounted on a multichip carrier structure. The separate die is required because process limitations and stringent cross talk requirements among all signal lines make implementation on a single die problematic.

### SUMMARY

Disclosed herein is a micro-electrical-mechanical-system (MEMS) switching device including a MEMS switch die that hosts a first MEMS switch having a first terminal and a second terminal and a second MEMS switch having a third terminal and a fourth terminal, the MEMS switch die oriented (oriented meaning arranged in line with a particular axis) in a device plane defined by an X-axis and a Y-axis. The switching device also includes a first input conductor, a second input conductor, a first output conductor, and a second output conductor, configured such that the first input conductor electrically connects the second terminal to the third terminal, the second input conductor, oriented along a Z-axis that is perpendicular to the X-axis and the Y-axis, electrically connects an input port to the first input conductor, the first output conductor electrically connects a first output port to the first terminal, the second output conductor electrically connects a second output port to the fourth terminal, wherein the first input conductor, the first output conductor, and the second output conductor are oriented in line with a common axis in the device plane. The common axis may be an arbitrary axis located within the device plane defined by the X-axis and the Y-axis. Further, a first path from the input port to the first output port, and a second path from the input port to the second output port, have substantially identical electrical characteristics.

The system may further include the second input conductor electrically connecting an input port to the first input conductor though a through-glass-via (TGV).

The system may further include the electrical characteristics including one or more of electrical resistance, trace width, trace length, material composition, layout geometry, spatial orientation, parasitic inductance, and/or parasitic capacitance.

The system may further include the first input conductor, the first output conductor, and the second output conductor being including a coplanar-waveguide ground plane structure including a first ground conductor and a second ground conductor disposed in the device plane with the first input conductor, the first output conductor and the second output conductor, wherein the first ground conductor and the second ground conductor are arranged on opposite sides of the device axis.

The system may further include the MEMS switch die that hosts a third MEMS switch having a fifth terminal and a sixth terminal and a fourth MEMS switch having a seventh terminal and an eighth terminal, a third input conductor, a fourth input conductor, a third output conductor, and a fourth output conductor, configured such that the third input conductor electrically connects the sixth terminal to the seventh terminal, the fourth input conductor, oriented along the Z-axis, electrically connects a second input port to the third input conductor, the third output conductor electrically connects a third output port to the fifth terminal, the fourth output conductor electrically connects a fourth output port to the eighth terminal. Further, the third input conductor, the third output conductor, and the fourth output conductor are oriented in line with a common axis in the device plane. The common axis may be an arbitrary axis located within the device plane defined by the X-axis and the Y-axis. And a third path from the second input port to the third output port, and a fourth path from the second input port to the fourth output port, have substantially identical electrical characteristics.

The system may further include a substrate having a first face and a second face, configured such that the device plane corresponds to the first face.

The system may also include a glass cap having a first face and a second face, and a cavity formed in the first face, the cap bonded to the MEMS switch die such that the first MEMS switch and the second MEMS switch are hermetically sealed within the cavity.

The system may further include the cap being a glass cap, and at least one through-glass-via (TGV) connects a ground plane to the coplanar-waveguide ground plane structure.

The system may further include both of the MEMS switch are single-pole-single-throw switches.

An additional embodiment includes a micro-electrical-mechanical-system (MEMS) switching device including a MEMS switch die that hosts a first MEMS switch having a first terminal and a second terminal, and a second MEMS switch having a third terminal and a fourth terminal, the MEMS switch die oriented in a device plane defined by an X-axis and a Y-axis. The switching device also includes a first input conductor, a second input conductor, a first output conductor, and a second output conductor, configured such that the first input conductor electrically connects the second terminal to the third terminal, the second input conductor electrically connects an input port to the first input conductor, the first output conductor electrically connects a first output port to the first terminal, and the second output conductor electrically connects a second output port to the fourth terminal. Further, the first input conductor, the first output conductor, and the second output conductor are oriented in line with a common axis in the device plane. The common axis may be an arbitrary axis located within the device plane defined by the X-axis and the Y-axis. A first path from the input port to the first output port, and a second path from the input port to the second output port, have substantially identical electrical characteristics. The first input conductor, the first output conductor, and the second output conductor are implemented by a coplanar-waveguide structure including a first ground conductor and a second ground conductor disposed in the device plane with the first input conductor, the first output conductor, and the second output conductor, wherein the first ground conductor and the second ground conductor are arranged on opposite sides of the device axis.

An embodiment includes the second input conductor is oriented along a Z-axis that is perpendicular to the X-axis and the Y-axis.

In an embodiment, the MEMS switch die includes a glass substrate having a first face and a second face, configured such that the device plane corresponds to the first face.

An additional embodiment is a method for switching output channels on a micro-electrical-mechanical-system (MEMS) switching device. The method includes hosting, via a MEMS switch die, a first MEMS switch having a first terminal and a second terminal and a second MEMS switch having a third terminal and a fourth terminal, the MEMS switch die oriented in a device plane defined by an X-axis and a Y-axis. The method then configures a first input conductor, a second input conductor, a first output conductor, and a second output conductor, such that the first input conductor electrically connects the second terminal to the third terminal, the second input conductor, oriented along a Z-axis, electrically connects an input port to the first input conductor, the first output conductor electrically connects a first output port to the first terminal, the second output conductor electrically connects a second output port to the fourth terminal. The method orients first input conductor, the first output conductor, and the second output conductor in line with a common device axis in the device plane. The common axis may be an arbitrary axis located within the device plane defined by the X-axis and the Y-axis. Next, the method maintains substantially identical electrical characteristics throughout the channels, where a first path from the input port to the first output port, and a second path from the input port to the second output port, have substantially identical electrical characteristics.

In an embodiment, the electrical characteristics comprise one or more of electrical resistance, trace width, trace length, material composition, layout geometry, spatial orientation, parasitic inductance, and/or parasitic capacitance.

In an embodiment, the first input conductor, the first output conductor, and the second output conductor are implemented by a coplanar-waveguide structure, the method includes disposing a first ground conductor and a second ground conductor in the device plane with the first input conductor, the first output conductor and the second output conductor, wherein the first ground conductor and the second ground conductor are arranged on opposite sides of the device axis.

In an embodiment, the method further includes hosting, via the MEMS switch die, a third MEMS switch having a fifth terminal and a sixth terminal and a fourth MEMS switch having a seventh terminal and an eighth terminal. The method also includes configuring a third input conductor, a fourth input conductor, a third output conductor, and a fourth output conductor, such that the third input conductor electrically connects the sixth terminal to the seventh terminal, the fourth input conductor, oriented along a Z-axis, electrically connects a second input port to the third input conductor, the third output conductor electrically connects a third output port to the fifth terminal, and the fourth output conductor electrically connects a fourth output port to the eighth terminal. The method also includes orienting the third input conductor, the third output conductor, and the fourth output conductor in line with a common axis in the device plane. The common axis may be an arbitrary axis located within the device plane defined by the X-axis and the Y-axis. The method maintains substantially identical electrical characteristics throughout the channels wherein a first path from at the input port to the first output port, and a second path from the input port to the second output port, have substantially identical electrical characteristics.

Another embodiment includes a method of manufacturing a micro-electrical-mechanical-system (MEMS) switching device. The method hosts, via a MEMS switch die, a first MEMS switch having a first terminal and a second terminal, and a second MEMS switch having a third terminal and a fourth terminal, the MEMS switch die is oriented in a device plane defined by an X-axis and a Y-axis. The method configures a first input conductor, a second input conductor, a first output conductor, and a second output conductor, such that the first input conductor electrically connects the second terminal to the third terminal, the second input conductor, oriented along a Z-axis, electrically connects an input port to the first input conductor, the first output conductor electrically connects a first output port to the first terminal, the second output conductor electrically connects a second output port to the fourth terminal. The method continues by orienting the first input conductor, the first output conductor, and the second output conductor in line with a common axis in the device plane. The common axis may be an arbitrary axis located within the device plane defined by the X-axis and the Y-axis. The method maintians substantially identical electrical characteristics throughout the channels wherein a first path from at the input port to the first output port, and a second path from the input port to the second output port, have substantially identical electrical characteristics.

In an embodiment for manufacturing a MEMS switching device, the electrical characteristics comprise one or more of electrical resistance, trace width, trace length, material composition, layout geometry, spatial orientation, parasitic inductance, and/or parasitic capacitance.

In an embodiment for manufacturing a MEMS switching device, the first input conductor, the first output conductor, and the second output conductor are implemented by a coplanar-waveguide structure. The method includes disposing a first ground conductor and a second ground conductor in the device plane with the first input conductor, the first output conductor and the second output conductor, wherein the first ground conductor and the second ground conductor are arranged on opposite sides of the device axis.

In an embodiment for manufacturing a MEMS switching device, the method includes hosting, via the MEMS switch die, a third MEMS switch having a fifth terminal and a sixth terminal and a fourth MEMS switch having a seventh terminal and an eighth terminal. The method configures a third input conductor, a fourth input conductor, a third output conductor, and a fourth output conductor, such that the third input conductor electrically connects the sixth terminal to the seventh terminal, the fourth input conductor, oriented along a Z-axis, electrically connects a second input port to the third input conductor, the third output conductor electrically connects a third output port to the fifth terminal, and the fourth output conductor electrically connects a fourth output port to the eighth terminal. The method orients the third input conductor, the third output conductor, and the fourth output conductor in line with a common axis in the device plane. The common axis may be an arbitrary axis located within the device plane defined by the X-axis and the Y-axis. The method maintains substantially identical electrical characteristics throughout the channels wherein a first path from at the input port to the first output port, and a second path from the input port to the second output port, have substantially identical electrical characteristics.

In an embodiment for manufacturing a MEMS switching device, the method includes a cap substrate having a first face and a second face, configured such that the device plane corresponds to the first face, and a ground plane is disposed on the second face.

In an embodiment for manufacturing a MEMS switching device, at least one through-substrate-via connects the ground plane to the at least two ground conductors.

In an embodiment for manufacturing a MEMS switching device, the MEMS switch is a single-pole-single-throw switch.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The foregoing will be apparent from the following more particular description of example embodiments, as illustrated in the accompanying drawings in which like reference characters refer to the same parts throughout the different views. The drawings are not necessarily to scale, emphasis instead being placed upon illustrating embodiments.

FIG. 1 is a schematic diagram of a legacy single-pole-double-throw switch for a differential signal.

FIG. 2A shows a schematic of a differential single-pole-single-throw (SPST) MEMS switch, according to an embodiment.

FIG. 2B shows a schematic of a differential single-pole-double-throw (SPDT) MEMS switch, according to an embodiment.

FIG. 2C shows a schematic of a differential double-pole-double-throw (DPDT) MEMS switch, according to an embodiment.

FIG. 3 shows a diagram of a coplanar-waveguide ground plane structure housing a MEMS switch, according to an embodiment.

FIG. 4A shows the top view of a ground plane of a coplanar-waveguide ground plane structure housing a MEMS switch, according to an embodiment.

FIG. 4B shows the bottom view of a ground plane of a coplanar-waveguide ground plane structure associated with a MEMS switch, according to an embodiment.

FIG. 5 shows a cross section (tilted view) of an air cavity where the MEMS switch is located within the die, according to an embodiment.

FIG. 6 shows the top view of a MEMS die housing a MEMS switch, according to an embodiment.

FIG. 7 shows the top view of a MEMS die housing a MEMS switch of FIG. 5 with the ground plane removed to show underneath, according to an embodiment.

FIG. 8 shows the top view of a MEMS die housing a MEMS switch of FIG. 5 with the ground plane removed to show underneath, and the substrate drawn in wireframe, according to an embodiment.

FIG. 9 shows the top view of a MEMS die housing a MEMS switch of FIG. 5 with the ground plane removed to show underneath, the substrate drawn in wireframe, and showing the connected and non-connected channel, according to an embodiment.

### DETAILED DESCRIPTION

A description of example embodiments follows.

While example embodiments have been particularly shown and described, it will be understood by those skilled in the art that various changes in form and details may be made therein without departing from the scope of the embodiments encompassed by the appended claims.

Microelectromechanical systems are an emerging technology for high power radio frequency (RF) and microwave switching applications. Unfortunately, single-pole-double-throw (SPDT) and double-pole-double-throw (DPDT) switches contain process limitations and stringent cross talk requirements among all signal lines making implementation on a single die problematic. As such, there is a need for a SPDT MEMS switch, and a double pole double throw (DPDT) MEMS switch, mounted on a single die which solves the cross talk downsides of existing SPDT MEMS switches.

Embodiments described herein are directed to a single micro-electromechanical system (MEMS) switch die design that contains one set of input port and two sets of output ports. The input port set can have two or more input signal terminals, and each output port can have two or more output signal terminals. An example MEMS switch die that has two terminals on each port with its output port terminals connecting or disconnecting to corresponding input terminals simultaneously, and thereby conveys a differential signal, the MEMS switch die is configured as a differential single-pole-double-throw (differential SPDT) switch. Another example MEMS switch die with the two terminals of each output terminals being independently controlled, or the input of device is fed with two independent signals, then the MEMS switch die is configured as double-pole-double-throw (DPDT) switch.

The system for a micro-electrical-mechanical-system (MEMS) switching device may include a MEMS switch die that hosts a first MEMS switch having a first terminal and a second terminal, and a second MEMS switch having a third terminal and a fourth terminal. The MEMS switch die may be oriented in a device plane defined by an X-axis and a Y-axis. The system also includes a first input conductor, a second input conductor, a first output conductor, and a second output conductor, constructed and arranged such that the first input conductor electrically connects the second terminal to the third terminal, the second input conductor, oriented along a Z-axis, electrically connects an input port to the first input conductor, the first output conductor electrically connects a first output port to the first terminal, and the second output conductor electrically connects a second output port to the fourth terminal. The system also includes the first input conductor, the first output conductor, and the second output conductor being oriented along a common axis in the device plane. In addition, a first path from the input port to the first output port, and a second path from the input port to the second output port, may have substantially identical electrical characteristics.

Maintaining substantially identical electrical characteristics is helpful in switching differential signals. The two polarities of a differential signal need to be processed in the same way, from the input of the device or switch to the output of the device or switch, for the differential signal to be interpreted properly at the receiver. If the electrical characteristics of each respective signal path through the device or switch are not identical, only one polarity of the differential signal may be modified, which may lead to an incorrect interpretation of the differential signal at the receiver. Relevant electrical characteristics may include, but are not limited to, electrical resistance, electrical impedance, trace width, trace length, material composition, layout geometry, spatial orientation, parasitic inductance, and or parasitic capacitance.

In this disclosure, the parallel signal path with one input and two selectable outputs on a single MEMS die with tight control of the impedance and phase delay can be achieved by using an edge coupled structure and through glass via (TGV) technology. An edge coupled structure with typical microwave design implementation, such as coplanar wave guide ground plane structure, strip-line, or microstrip, can be adopted. The implementation can support the performance to accommodate signals up to and exceeding 60 GHz with little or no degradation.

Embodiments are intended for high-speed digital applications but can also be used for general RF/Microwave and AC/DC applications, which require simultaneous multiple inputs and multiple outputs.

Previously attempted implementations of a differential single-pole-double-throw (SPDT) switch (or a general DPDT switch) using micro-electromechanical system (MEMS) technology typically required fabrication of two separate, single channel switch die, mounting the two single channel switch die on a multi-layer substrate, then routing each component of the differential signal through different layers in the substrate. The separate die are required because process limitations and stringent cross talk requirements among all signal lines make implementation on a single die problematic.

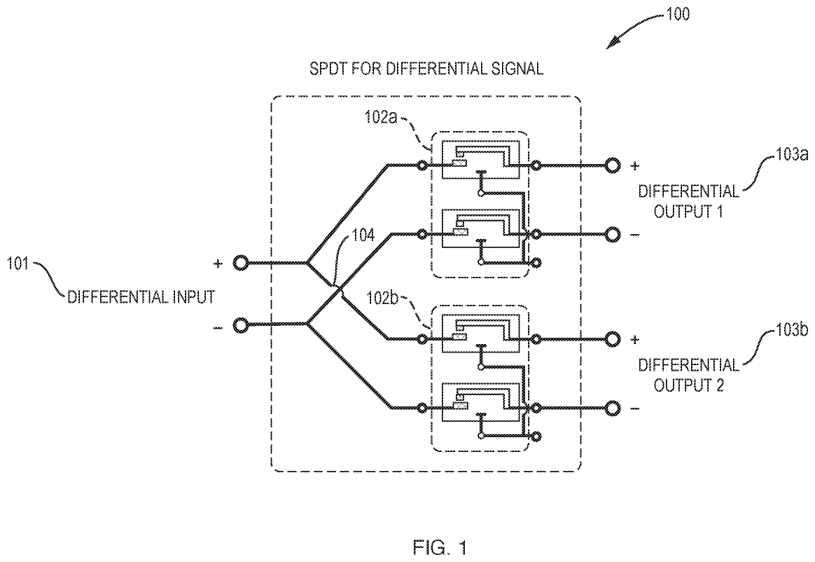

FIG. 1 is a schematic diagram of a single-pole-double-throw switch 100 for a differential signal. The differential input 101 leads to two pairs of MEMS switches 102a and 102b, which allows for two sets of differential outputs 103a and 103b. In this schematic example, the positive trace from the differential input 101 must cross over the negative trace from the differential input 101 at 104. This small difference in trace geometry and length can have significant effects on the way the differential signal flows through the MEMS switch.

Example embodiments disclosed herein employ an edged-coupled microwave structure, such as a coplanar-waveguide (CPW) structure or a grounded coplanar-waveguide (GCPW) structure (also referred to herein as a coplanar-waveguide ground plane structure), to achieve a coupled differential signal path with through-glass via technology in order to a achieve a differential SPDT switch, or general DPDT switch, on a single die. The input terminal may be situated in the middle of the die, and the two output ports may be situated on opposite sides of the die. All signal paths are implemented with a controlled edge-coupled structure, resulting in a consistent, well-defined differential impedance (100Ω, for example) throughout the entire signal path from input port to output ports.

Because the input port placement is in the middle of the device, and output ports are disposed on the edge of die and aligned with the input port, the layout of the edge-coupled trace from the two input terminals to the two output terminals can be matched with a negligible phase difference between the two signal paths.

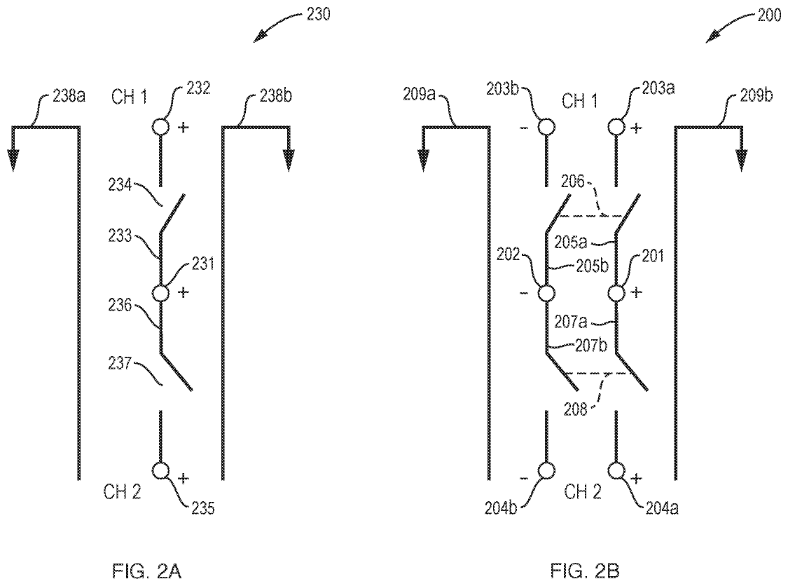

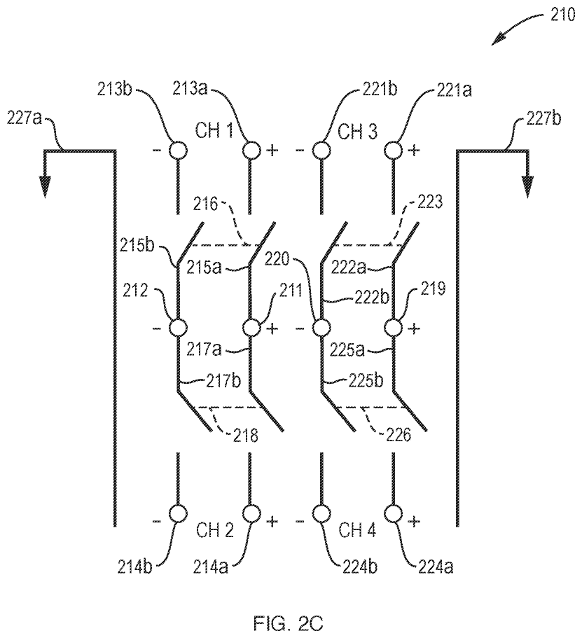

FIG. 2A shows a schematic of a differential single-pole-single-throw (SPST) MEMS switch 230, according to an embodiment. The input terminal 231 is located in the center of the switch and extends down through a gap in the ground plane of the MEMS device the SPST switch is located on. The input terminal 231 connects to the Channel 1 output 232 through conductor 233 and a first switch 234, and to the Channel 2 output 235 though conductor 236 and a second switch 237. The SPST MEMS switch components (i.e., the conductors, the first switch, and the second switch) are located between two coplanar-waveguide ground planes 238a and 238b, forming an edge-coupled microwave structure (ground planes 238a-b) such as a coplanar-waveguide ground plane structure. The SPST MEMS switch components may be positioned within an air cavity within the device cap below a top ground plane on the device cap, below a dielectric layer (in example embodiments, the device cap is glass), and above the MEMS substrate (in example embodiments, the MEMS substrate is glass). This MEMS substrate may further comprise a bottom ground plane, so that the SPST MEMS switch components are disposed between the top ground plane (on top of the device cap) and the bottom ground plane (on the bottom of the glass substrate).

FIG. 2B shows a schematic of a differential single-pole-double-throw (SPDT) MEMS switch 200, according to an embodiment. The two input terminals 201 (+) and 202 (−) are located in the center of the switch and extend down through a gap in the ground plane of the MEMS device on which the SPDT switch is located. The two input terminals 201 and 202 connect to Channel 1 outputs 203a (+) and 203b (−) through conductors 205a-b and a first pair of switches 206, and to Channel 2 outputs 204a (+) and 204b (−) through conductors 207a-b and a second pair of switches 208. The SPDT switch components (i.e., the conductors, the first pair of switches and the second pair of switches) are located between two coplanar-waveguide ground planes 209a-b, forming an edged-coupled microwave structure (ground planes 209a-b) such as a coplanar-waveguide ground plane structure. The SPDT MEMS switch components may be positioned within an air cavity within the device cap below a top ground plane on the device cap, below a dielectric layer (in example embodiments, the device cap is glass), and above the MEMS substrate (in the example embodiments, the MEMS substrate is glass). This MEMS substrate may further comprise a bottom ground plane, so that the SPDT MEMS switch components are disposed between the top ground plane (on top of the device cap) and the bottom ground plane (on the bottom of the glass substrate).

FIG. 2C shows a schematic of a differential double-pole-double-throw (DPDT) MEMS switch 210, according to an embodiment. Two input terminals 211 (+) and 212 (−) are located in the center of the switch and extend down through a gap in the ground plane of the MEMS device the SPDT switch is located on. The two input terminals 211 (+) and 212 (−) connect to Channel 1 outputs 213a (+) and 213b (−) through conductors 215a-b and a first pair of switches 216, and to Channel 2 outputs 214a (+) and 214b (−) through conductors 217a-b and a second pair of switches 218. In addition, two input terminals 219 (+) and 220 (−) connect to Channel 3 outputs 221a (+) and 221b (−) through conductors 222a-b and a first pair of switches 223, and to Channel 4 outputs 224a (+) and 224b (−) through conductors 225a-b and a second pair of switches 226. The DPDT switch components (i.e., the conductors, the first pair of switches and the second pair of switches) are located between two coplanar-waveguide ground planes 227a-b, forming an edged-coupled microwave structure (ground planes 227a-b) such as a coplanar-waveguide ground plane structure. The DPDT MEMS switch components may be positioned within an air cavity within the device cap below a top ground plane on the device cap, below a dielectric layer (i.e., the glass device cap), and above the glass MEMS substrate. This MEMS substrate may further comprise a bottom ground plane, so that the DPDT MEMS switch components are disposed between the top ground plane (on top of the device cap) and the bottom ground plane (on the bottom of the glass substrate).

The noise rejection and EMI protection of signal line are supported by the structure design, e.g., coplanar-waveguide ground plane structure. A “picket fence” or wall of vias may be implemented to electrically couple the coplanar-waveguide ground plane structure (i.e., the ground planes that are coplanar with the signal lines) to the top and bottom ground planes.

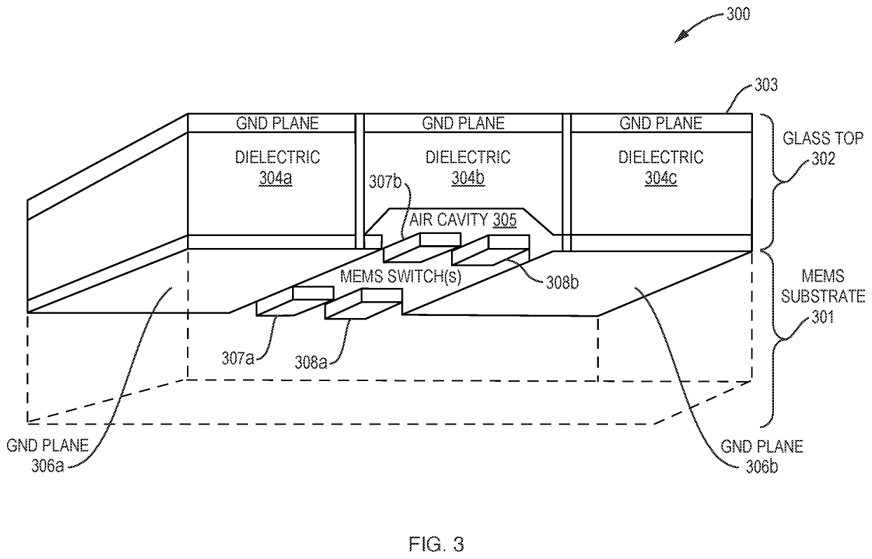

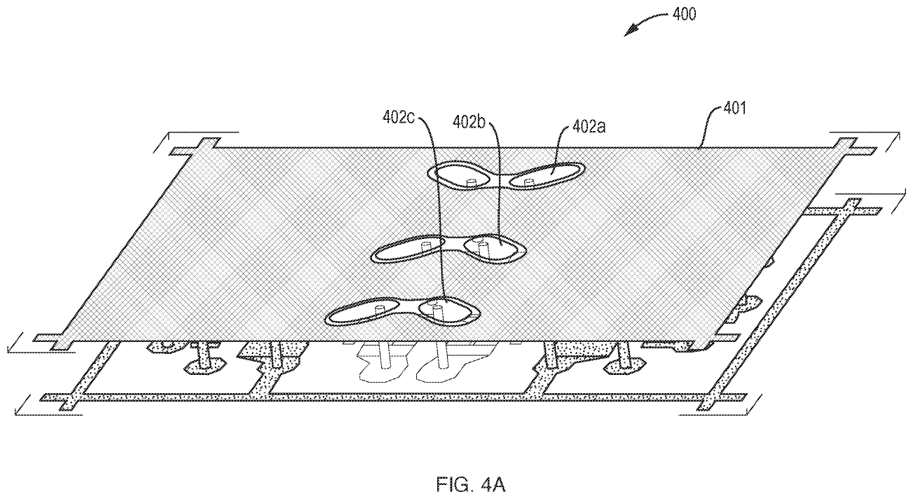

FIG. 3 shows a diagram 300 of a coplanar-waveguide ground plane structure for use with a MEMS switch, according to an example embodiment. The MEMS device, which includes ground planes 306a and 306b, conductors 307a-b and 308a-b, and MEMS switches (not shown for clarity), sits on a MEMS substrate 301. The MEMS substrate may be a glass substrate. The conductors 307a-b and 308a-b may be separated into conductor segment, and the MEMS switches (not shown for clarity) are disposed between the conductor segments as depicted in FIG. 2A. The cap 302 comprises dielectric materials 304a-b (e.g., glass), as well as the top ground plane 303, and coplanar-waveguide ground plane structure 306a-b. An air cavity 305 exists above the two conductors 307a-b and 308a-b, the air cavity 305 allows for the MEMS switch to operate and will be hermetically sealed once the cap 302 is installed. The MEMS switch devices and the signal lines on the MEMS substrate extend into the air cavity 305. Input terminals extend through the MEMS substrate 301 as vias and connect to the conductors 307 and 308.

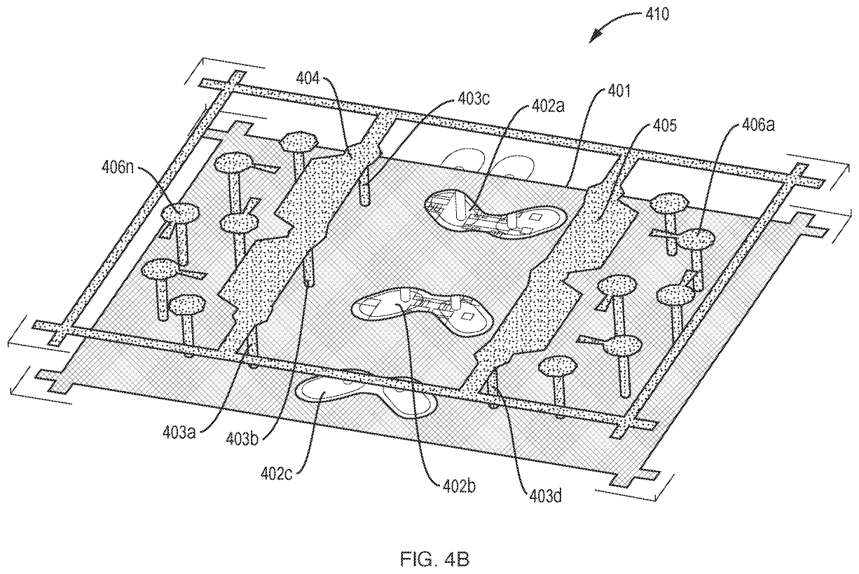

FIG. 4A shows the top view 400 of a glass cap for a coplanar-waveguide structure housing a MEMS switch, according to an example embodiment. The top ground plane 401 contains cutouts 402a-c which allow for input vias and output vias to extend through the glass cap without electrically coupling to the top ground plane 401. A cavity is fabricated in the glass cap to provide space for components (e.g., MEMS switches) on the device substrate. The glass cap is placed atop the MEMS device substrate and sealed with a sealing technique (such as thermo-compression bonding) thereby hermetically sealing the device cavity from contaminants.

FIG. 4B shows the bottom view 410 of the glass cap shown in FIG. 4A, which includes the top ground plane 401, according to an embodiment. The ground plane 401 contains cutouts 402a-c which allow for input vias and output vias to extend through the glass cap without electrically coupling to the top ground plane 401. The glass substrate will be placed atop the ground plane, sealing the air gaps from contaminants. Through-glass-vias (TGVs) 403a-d (two additional TGVs are present but are hidden from view by the coplanar-waveguide ground plane 405) connect the ground plane 401 to the coplanar-waveguide ground planes 404 and 405. TGVs 406a-n are present to electrically couple the ground plane 401 through the glass cap to components at the interface between the glass cap and the glass device substrate.

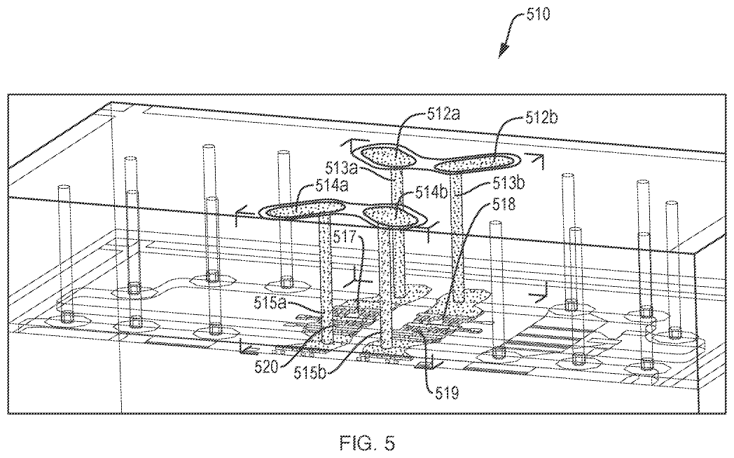

FIG. 5 shows a cross section 510 (tilted view) of air cavities where the MEMS switches are located within the die, according to an embodiment. This exemplary switching device contains one pair of differential inputs and one pair of differential outputs. Channel 1 input signals 512a and 512b are connected to TGV conductors 513a-b which extend downward towards the MEMS switches 517 and 518. Channel 1 output signals 514a and 514b are connected to TGV conductors 515a-b which extend downward towards the MEMS switches 519 and 520.

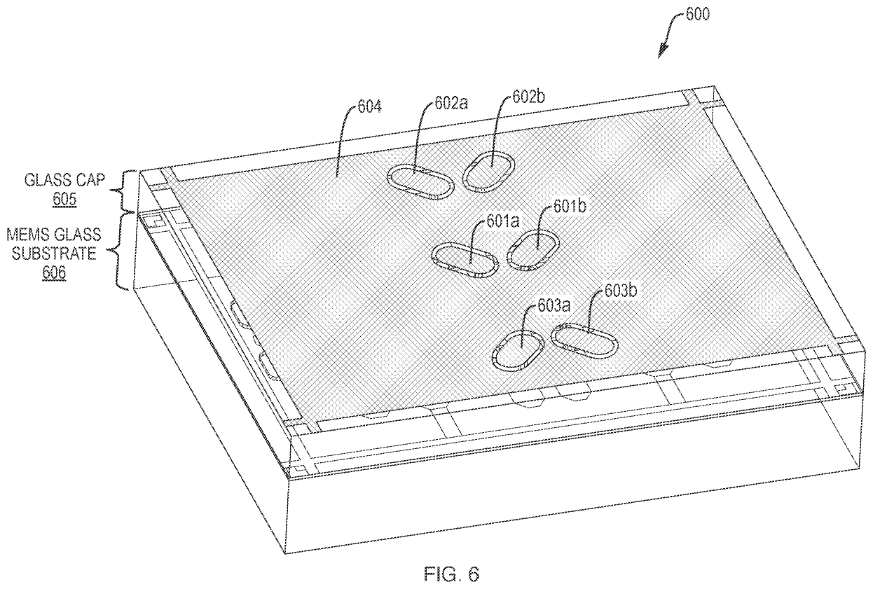

FIG. 6 shows the top view 600 of a MEMS die housing a MEMS switch, according to an embodiment. The top view 600 shows how the differential input signal pair 601a-b is located in a central region between the two differential output signal pairs, 602a-b and 603a-b respectively. Cutouts are located around the input signal pair 601a-b, and both sets of output signal pairs 602a-b and 603a-b and separate the ground plane 604 from the signal pairs connection points. The connection points for the signal pairs are located within the glass cap 605, which sits atop the MEMS glass substrate 606.

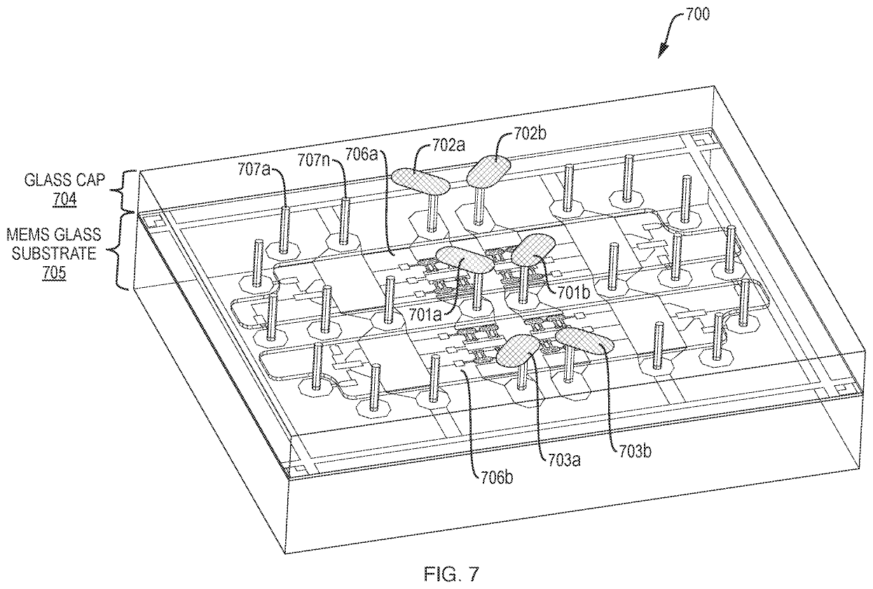

FIG. 7 shows the top view 700 of a MEMS die housing a MEMS switch of FIG. 6 with the ground plane removed to show underneath, according to an embodiment. The top view 700 shows how the input signal pair 701a-b are located in a central region between the two output signal pairs, 702a-b and 703a-b respectively. The connection points for the signal pairs are located within the glass cap 704, which sits atop the MEMS glass substrate 705. The air pocket cavities 706a-b house the switching components of the MEMS switch within the glass substrate 705 and are sealed with the glass cap 704. Through-glass-vias (TGVs) 707a-n connect the ground plane of the substrate 705 to the (not visible) top ground plane.

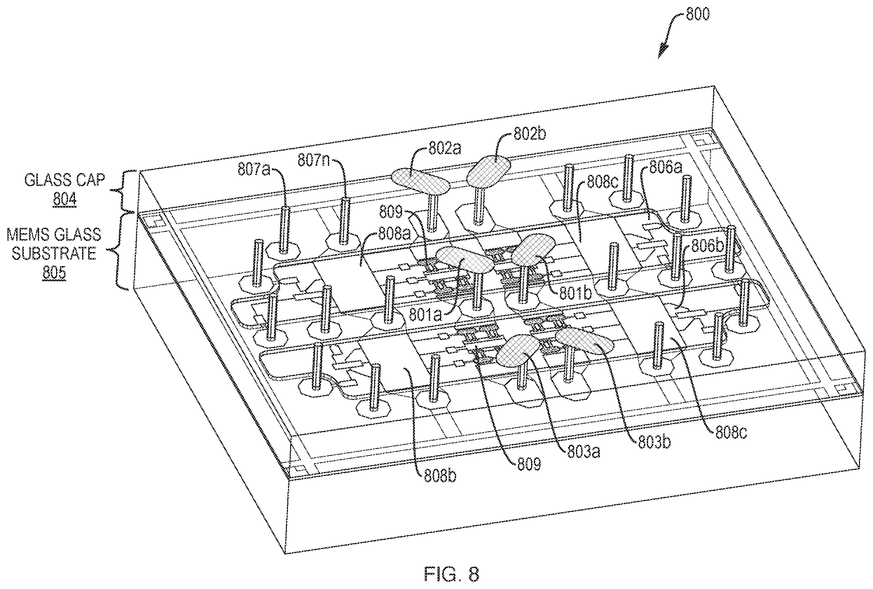

FIG. 8 shows the top view 800 of a MEMS die housing the MEMS switch of FIG. 6 with the ground plane removed to show underneath, and the substrate drawn in wireframe, according to an embodiment. The top view 800 shows how the input signal pair 801a-b are located in a central region between the two output signal pairs, 802a-b and 803a-b respectively. The connection points for the signal pairs are located within the glass cap 804, which sits atop the MEMS glass substrate 805. The air pocket cavities 806a-b house the switching components of the MEMS switch within the glass substrate 805 and are sealed with the glass cap 804. Through-glass-vias (TGVs) 807a-n connect the ground plane of the substrate 805 to the (not visible) top ground plane. Coplanar-waveguide ground traces 808a-d are shown encompassing the switching components 809 and extend from the edges of the perimeter ground plane structure and run the full length of the substrate, enveloping the MEMS switches in a coplanar-waveguide ground plane structure.

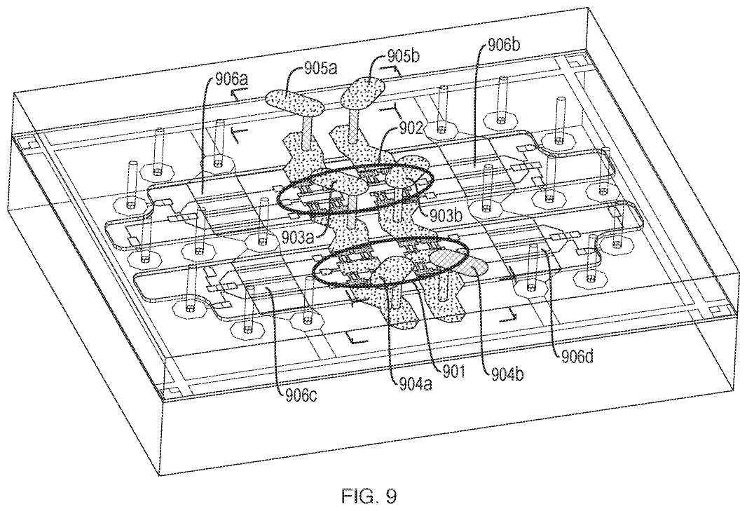

FIG. 9 shows the top view 900 of a MEMS die housing a MEMS switch of FIG. 6 with the ground plane removed to show underneath, the substrate drawn in wireframe, and showing the connected and non-connected channel, according to an embodiment. The channel 901 can be seen as visibly closed, sending power from the input signal pair 903a-b to the output signal pair 904a-b. The channel 902 can be seen as visibly open, therefore no power will come from the input signal pair 903a-b to the output signal pair 905a-b. Coplanar-waveguide ground traces 906a-d are shown encompassing the switching components 809 and extend from the edges of the perimeter ground plane structure and run the full length of the substrate, enveloping the MEMS switches in a coplanar-waveguide ground plane structure.

While example embodiments have been particularly shown and described, it will be understood by those skilled in the art that various changes in form and details may be made therein without departing from the scope of the embodiments encompassed by the appended claims.

What is claimed is:

1. A micro-electrical-mechanical-system (MEMS) switching device, comprising:
a MEMS switch die that hosts a first MEMS switch having a first terminal and a second terminal, and a second MEMS switch having a third terminal and a fourth terminal, the MEMS switch die oriented in a device plane defined by an X-axis and a Y-axis;
a first input conductor, a second input conductor, a first output conductor, and a second output conductor, configured such that:
(i) the first input conductor electrically connects the second terminal to the third terminal;
(ii) the second input conductor, oriented along a Z-axis that is perpendicular to the X-axis and the Y-axis, electrically connects an input port to the first input conductor;
(iii) the first output conductor electrically connects a first output port to the first terminal;
(iv) the second output conductor electrically connects a second output port to the fourth terminal;
wherein the first input conductor, the first output conductor, and the second output conductor are oriented in line with a common axis in the device plane; and
wherein a first path from the input port to the first output port, and a second path from the input port to the second output port, have substantially identical electrical characteristics.

2. The MEMS switching device of claim 1, wherein the second input conductor electrically connects an input port to the first input conductor through a through-glass-via (TGV).

3. The MEMS switching device of claim 1, wherein the electrical characteristics comprise one or more of electrical resistance, trace width, trace length, material composition, layout geometry, spatial orientation, parasitic inductance, and/or parasitic capacitance.

4. The MEMS switching device of claim 1, wherein the first input conductor, the first output conductor, and the second output conductor comprise a coplanar-waveguide structure comprising:
a first ground conductor and a second ground conductor disposed in the device plane with the first input conductor, the first output conductor, and the second output conductor, wherein the first ground conductor and the second ground conductor are arranged on opposite sides of the device axis.

5. The MEMS switching device of claim 4, further comprising:
the MEMS switch die that hosts a third MEMS switch having a fifth terminal and a sixth terminal and a fourth MEMS switch having a seventh terminal and an eighth terminal;
a third input conductor, a fourth input conductor, a third output conductor, and a fourth output conductor, configured such that:
(i) the third input conductor electrically connects the sixth terminal to the seventh terminal;
(ii) the fourth input conductor, oriented along the Z-axis, electrically connects a second input port to the third input conductor;
(iii) the third output conductor electrically connects a third output port to the fifth terminal;
(iv) the fourth output conductor electrically connects a fourth output port to the eighth terminal;
wherein the third input conductor, the third output conductor, and the fourth output conductor are oriented in line with a common axis in the device plane; and
wherein a third path from the second input port to the third output port, and a fourth path from the second input port to the fourth output port, have substantially identical electrical characteristics.

6. The MEMS switching device of claim 4, wherein the MEMS switch die comprises a substrate having a first face and a second face, configured such that the device plane corresponds to the first face.

7. The MEMS switching device of claim 4, further comprising a cap having a first face and a second face, and a cavity formed in the first face, the glass cap bonded to the MEMS switch die such that the first MEMS switch and the second MEMS switch are hermetically sealed within the cavity.

8. The MEMS switching device of claim 7, wherein the cap is a glass cap, and at least one through-glass-via (TGV) connects a ground plane to the coplanar-waveguide ground plane structure.

9. The MEMS switching device of claim 1, wherein both of the MEMS switch are a single-pole-single-throw switch.

10. A micro-electrical-mechanical-system (MEMS) switching device, comprising:
a MEMS switch die that hosts a first MEMS switch having a first terminal and a second terminal, and a second MEMS switch having a third terminal and a fourth terminal, the MEMS switch die oriented in a device plane defined by an X-axis and a Y-axis;
a first input conductor, a second input conductor, a first output conductor, and a second output conductor, configured such that:
(i) the first input conductor electrically connects the second terminal to the third terminal;
(ii) the second input conductor electrically connects an input port to the first input conductor;
(iii) the first output conductor electrically connects a first output port to the first terminal;
(iv) the second output conductor electrically connects a second output port to the fourth terminal;
wherein the first input conductor, the first output conductor, and the second output conductor are oriented in line with a common axis the device plane;
wherein a first path from the input port to the first output port, and a second path from the input port to the second output port, have substantially identical electrical characteristics; and
wherein the first input conductor, the first output conductor, and the second output conductor are implemented by a coplanar-waveguide structure comprising:
a first ground conductor and a second ground conductor disposed in the device plane with the first input conductor, the first output conductor, and the second output conductor, wherein the first ground conductor and the second ground conductor are arranged on opposite sides of the device axis.

11. The MEMS switching device of claim 10, wherein the second input conductor is oriented along a Z-axis that is perpendicular to the X-axis and the Y-axis.

12. The MEMS switching device of claim 10, wherein the electrical characteristics comprise one or more of electrical resistance, trace width, trace length, material composition, layout geometry, spatial orientation, parasitic inductance, and/or parasitic capacitance.

13. The MEMS switching device of claim 10, wherein the MEMS switch die comprises a glass substrate having a first face and a second face, configured such that the device plane corresponds to the first face.

14. The MEMS switching device of claim 10, further comprising a glass cap having a first face and a second face, and a cavity formed in the first face, the glass cap bonded to the MEMS switch die such that the first MEMS switch and the second MEMS switch is hermetically sealed within the cavity.

15. A method of manufacturing a micro-electrical-mechanical-system (MEMS) switching device, comprising:
hosting, via a MEMS switch die, a first MEMS switch having a first terminal and a second terminal, and a second MEMS switch having a third terminal and a fourth terminal, the MEMS switch die oriented in a device plane defined by an X-axis and a Y-axis;
configuring a first input conductor, a second input conductor, a first output conductor, and a second output conductor, such that:
(i) the first input conductor electrically connects the second terminal to the third terminal;
(ii) the second input conductor, oriented along a Z-axis, electrically connects an input port to the first input conductor;
(iii) the first output conductor electrically connects a first output port to the first terminal;
(iv) the second output conductor electrically connects a second output port to the fourth terminal;
orienting the first input conductor, the first output conductor, and the second output conductor in line with a common axis in the device plane; and
maintaining substantially identical electrical characteristics throughout the channels wherein a first path from at the input port to the first output port, and a second path from the input port to the second output port, have substantially identical electrical characteristics.

16. The method of manufacturing a MEMS switching device of claim 15, wherein the electrical characteristics comprise one or more of electrical resistance, trace width, trace length, material composition, layout geometry, spatial orientation, parasitic inductance, and/or parasitic capacitance.

17. The method of manufacturing a MEMS switching device of claim 15, wherein the first input conductor, the first output conductor, and the second output conductor are implemented by a coplanar-waveguide structure, the method comprising:
disposing a first ground conductor and a second ground conductor in the device plane with the first input conductor, the first output conductor and the second output conductor, wherein the first ground conductor and the second ground conductor are arranged on opposite sides of the device axis.

18. The method of manufacturing a MEMS switching device of claim 17, further comprising:
hosting, via the MEMS switch die, a third MEMS switch having a fifth terminal and a sixth terminal and a fourth MEMS switch having a seventh terminal and an eighth terminal;
configuring a third input conductor, a fourth input conductor, a third output conductor, and a fourth output conductor, such that:
(v) the third input conductor electrically connects the sixth terminal to the seventh terminal;
(vi) the fourth input conductor, oriented along a Z-axis, electrically connects a second input port to the third input conductor;
(vii) the third output conductor electrically connects a third output port to the fifth terminal;
(viii) the fourth output conductor electrically connects a fourth output port to the eighth terminal;
orienting the third input conductor, the third output conductor, and the fourth output conductor in line with a common axis in the device plane; and
maintaining substantially identical electrical characteristics throughout the channels wherein a first path from at the input port to the first output port, and a second path from the input port to the second output port, have substantially identical electrical characteristics.

19. The method of manufacturing a MEMS switching device of claim 17, further comprising a cap substrate having a first face and a second face, configured such that the device plane corresponds to the first face, and a ground plane is disposed on the second face.

20. The method of manufacturing a MEMS switching device of claim 19, wherein at least one through-substrate-via connects the ground plane to the at least two ground conductors.

21. The of manufacturing a MEMS switching device of claim 15, wherein the MEMS switch is a single-pole-single-throw switch.
